(19) United States
(12) Patent Application Publication
(10) Pub. No.: US 2013/0328638 A1
(43) Pub. Date: Dec. 12, 2013

(54) VOLTAGE-CONTROLLED-OSCILLATOR (VCO) ARCHITECTURE FOR REDUCING DISTURBANCE

(71) Applicants: Tienya Chang, Carlsbad, CA (US); Sheng Ye, Carlsbad, CA (US)

(72) Inventors: Tienya Chang, Carlsbad, CA (US); Sheng Ye, Carlsbad, CA (US)

(21) Appl. No.: 13/915,283

(22) Filed: Jun. 11, 2013

Related U.S. Application Data
(60) Provisional application No. 61/658,032, filed on Jun. 11, 2012.

(51) Int. Cl. H03L 7/00

(52) U.S. Cl. CPC H03L 7/00
USPC 331/36 R

(57) ABSTRACT

Operations of a signal generator, which may be configurable to generate signals at one or more particular frequencies, may be controlled. The controlling may occur by setting frequency of an output of the signal generator by setting one or both of impedance and capacitance associated with the signal generator; and tuning the signal generator by applying one or more adjustments to the impedance and the capacitance associated with the signal generator, to maintain the set frequency. The signal generator may comprise a phase-locked loop (PLL), comprising a voltage controlled oscillator (VCO) for use in generating oscillating signals driving the generation of the PLL output. The VCO may be configurable to generate signals at varying frequencies, and may comprise at least one impedance element, at least one variable capacitance element and a plurality of tuning branches, where each tuning branch comprises at least a static capacitance element and a switching element.

### CLAIM OF PRIORITY

This patent application makes reference to, claims priority to and claims benefit from the U.S. Provisional Patent Application Ser. No. 61/658,032, filed on Jun. 11, 2012, and entitled “METHOD AND SYSTEM FOR VOLTAGE-CONTROLLED-OSCILLATOR (VCO) ARCHITECTURE FOR REDUCING DISTURBANCE OF DEMODULATOR.”

The above stated application is hereby incorporated herein by reference in its entirety.

### TECHNICAL FIELD

Aspects of the present application relate to communications. More specifically, certain implementations of the present disclosure relate to voltage-controlled-oscillator (VCO) architecture for reducing disturbance.

### BACKGROUND

Existing methods and systems for voltage-controlled-oscillator (VCO) can introduce disturbances and/or handle such disturbances in inefficient manner. In this regard, communication via wireless and/or wired connections may comprise reception and/or transmission of radio frequency (RF) signals. For example, communication devices may transmit and/or receive RF signals carrying exchanged data, with the RF signals being configured in accordance with corresponding wired and/or wireless protocols or standards. Accordingly, signal processing (e.g., of RF signals) must be performed during wireless and/or wired communications to enable proper exchange of information. Example signal processing operations may comprise filtering, amplification, up-conversion/down-conversion of baseband signals, modulation/demodulation, analog-to-digital conversions and digital-to-analog conversions, encoding/decoding, and/or encryption/decryption.

Further limitations and disadvantages of conventional and traditional approaches will become apparent to one of skill in the art, through comparison of such approaches with some aspects of the present method and apparatus set forth in the remainder of this disclosure with reference to the drawings.

### BRIEF SUMMARY

A system and/or method is provided for voltage-controlled-oscillator (VCO) architecture for reducing disturbance, substantially as shown in and/or described in connection with at least one of the figures, as set forth more completely in the claims.

These and other advantages, aspects and novel features of the present disclosure, as well as details of illustrated implementation(s) thereof, will be more fully understood from the following description and drawings.

### BRIEF DESCRIPTION OF SEVERAL VIEWS OF THE DRAWINGS

FIG. 1 illustrates an example electronic device that utilizes voltage-controlled-oscillator (VCO), which may be used in accordance with various implementations of the invention.

FIG. 2 illustrates an example variable capacitor based component of a voltage-controlled-oscillator (VCO), in accordance with an implementation of the invention.

FIG. 3 illustrates an example use of ramping signals for controlling switching of capacitors in a voltage-controlled-oscillator (VCO), in accordance with an implementation of the invention.

FIG. 4 illustrates an example ramping sequence in a voltage-controlled-oscillator (VCO), in accordance with an implementation of the invention.

FIG. 5 is a flow chart that illustrates example process for controlling of capacitance ramping in a voltage-controlled-oscillator (VCO), in accordance with an implementation of the invention.

### DETAILED DESCRIPTION

Certain implementations of the invention may be found in method and system for voltage-controlled-oscillator (VCO) architecture for reducing disturbance. As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first plurality of lines of code and may comprise a second “circuit” when executing a second plurality of lines of code. As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the terms “block” and “module” refer to functions than can be performed by one or more circuits. As utilized herein, the term “example” means serving as a non-limiting example, instance, or illustration. As utilized herein, the terms “for example” and “e.g.,” introduce a list of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled, or not enabled, by some user-configurable setting.

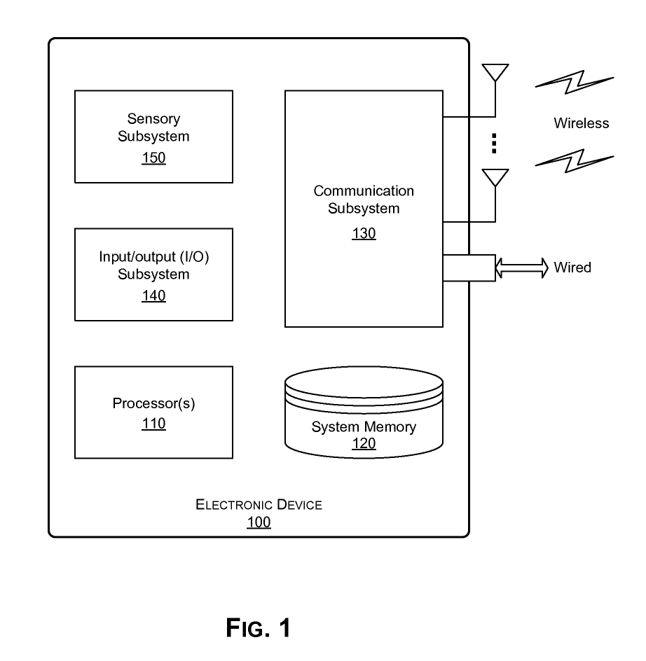

FIG. 1 illustrates an example electronic device that utilizes voltage-controlled-oscillator (VCO), which may be used in accordance with various implementations of the invention. Referring to FIG. 1, there is shown an electronic device 100.

The electronic device 100 may comprise suitable circuitry, interfaces, logic, and/or code for implementing various aspects of the inventions. In this regard, the electronic device 100 the electronic device may be configured to support performing, executing or running various operations, functions, applications and/or services. For example, the electronic device 100 may be operable to support, in some instances, such operations as communication operations, processing or handling of data, input/output operations, or the like. In this regard, the electronic device 100 may enable and/or support communication of data, such as via wired and/or wireless connections, which may be configured in accordance with one or more supported wireless and/or wired protocols or standards. To support input/output operations, the electronic device 100 may comprise components or subsystems for enabling interactions with a user (e.g., end-user or installer), so as to obtain user input and/or to provide user output. In some instances, the electronic device 100 may be a handheld mobile device—i.e., be intended for use on the move and/or at different locations. In this regard, the electronic device 100 may be designed and/or configured to allow for ease of movement, such as to allow it to be readily moved while being held by the user as the user moves, and the electronic device 100 may be configured to perform at least some of the operations, functions, applications and/or services supported by the device on the move. Examples of electronic devices may comprise set-top boxes, televisions, displays, gateways, modems, access points, femtocells, computers, cellular phones, smartphones, tablets, and or any other network node. The disclosure, however, is not limited to any particular type of electronic device.

The electronic device 100 may comprise, for example, one or more processors 110, a system memory 120, a communication subsystem 130, an input/output (I/O) subsystem 140, and a sensory subsystem 150.

The processor 110 may comprise suitable circuitry, interfaces, logic, and/or code that may be operable to perform general and/or specialized processing operations in the electronic device 110. For example, the processor 110 may comprise a general purpose processor (e.g., a central processing unit or CPU), a special purpose processor (e.g., graphics processing unit or GPU, or a visual processing unit or VPU), or the like. The disclosure, however, is not limited to any particular type of processor. When utilized as a general purpose processor, the processor 110 may be operable to, for example, process or handle data, control or manage operations of the electronic device 100, and/or handle or support tasks and/or applications performed therein. In this regard, the processor 110 may be utilized to configure and/or control operations of various components and/or subsystems of the electronic device 100, by utilizing, for example, one or more control signals. In some instances, however, the processor 110 may comprise a specialized processor, such as a video/graphics processor or a dedicated application processor that may be utilized for running and/or executing applications (or programs) in the electronic device 100.

The system memory 120 may comprise suitable circuitry, interfaces, logic, and/or code that may enable permanent and/or non-permanent storage, buffering, and/or fetching of data, code and/or other information, which may be used, consumed and/or processed. In this regard, the system memory 120 may comprise different memory technologies, including, for example, read-only memory (ROM), random access memory (RAM), Flash memory, solid-state drive (SSD), and/or field-programmable gate array (FPGA). The disclosure, however, is not limited to any particular type of memory or storage device. The system memory 120 may store, for example, configuration data, which may comprise parameters and/or code, comprising software and/or firmware. The disclosure is not limited, however, to any particular type of configuration data.

The communication subsystem 130 may comprise suitable circuitry, interfaces, logic, and/or code operable to communicate data from and/or to the electronic device, such as via one or more wired and/or wireless connections. The communication subsystem 130 may be configured to support one or more wired protocols and/or interfaces, and/or one or more wireless protocols and/or interfaces, facilitating transmission and/or reception of signals to and/or from the electronic device 100 and/or processing of transmitted or received signals in accordance with applicable wired or wireless protocols. Examples of wireless protocols or standards that may be supported and/or used by the communication subsystem 130 may comprise wireless personal area network (WPAN) protocols, such as Bluetooth (IEEE 802.15); near field communication (NFC) standards; wireless local area network (WLAN) protocols, such as WiFi (IEEE 802.11); cellular standards, such as 1G/2G+(e.g., GSM/GPRS/EDGE, and IS-95 or cdmaOne) and/or 1G/2G+(e.g., CDMA2000, UMTS, and HSPA); 4G standards, such as WiMAX (IEEE 802.16) and LTE; Ultra-Wideband (UWB), and/or the like. Examples of wired protocols and/or interfaces that may be supported and/or used by the communication subsystem 130 comprise Ethernet (IEEE 802.2), Fiber Distributed Data Interface (FDDI), Integrated Services Digital Network (ISDN), cable (DOCSIS) and Universal Serial Bus (USB) based interfaces. Examples of signal processing operations that may be performed by the communication subsystem 130 comprise, for example, filtering, amplification, analog-to-digital conversion and/or digital-to-analog conversion, up-conversion/down-conversion of baseband signals, encoding/decoding, encryption/decryption, and/or modulation/demodulation.

The I/O subsystem 140 may comprise suitable circuitry, interfaces, logic, and/or code for enabling and/or managing user (e.g., end-user or installer) interactions with the electronic device 100, such as obtaining input from, and/or to providing output to, the device user(s). The I/O subsystem 140 may support various types of inputs and/or outputs, including, for example, video, audio, and/or text. In this regard, dedicated I/O devices and/or components, external to (and coupled with) or integrated within the electronic device 100, may be utilized for inputting and/or outputting data during operations of the I/O subsystem 140. Examples of such dedicated I/O devices may comprise displays, audio I/O components (e.g., speakers and/or microphones), mice, keyboards, touch screens (or touchpads), and the like. In some instances, user input obtained via the I/O subsystem 140, may be used to configure and/or modify various functions of particular components or subsystems of the electronic device 100.

The sensory subsystem 150 may comprise suitable circuitry, interfaces, logic, and/or code for obtaining and/or generating sensory information, which may relate to the electronic device 100, its user(s), and/or its environment. For example, the sensory subsystem 150 may comprise ambient conditions (e.g., temperature, humidity, or light) sensors, positional or location sensors (e.g., GPS or other GNSS based sensors), and/or motion related sensors (e.g., accelerometer, gyroscope, pedometers, and/or altimeters).

In operation, the electronic device 100 may be utilized (e.g., by a user) to perform, execute and/or run various operations, functions, applications or services, such as using pre-configured instructions and/or based on real-time user instructions or interactions. In this regard, various types of operations, functions, applications or services may be available in or supported by the electronic device 100. For example, the electronic device 100 may be used for executing programs, playing video and/or audio content, gaming, email applications (and/or similar type of web based communications), calling services (e.g., voice calls), networking services (e.g., WiFi hotspot, Bluetooth piconet, and/or active 3G/femtocell data channels), or the like. The disclosure, however, is not limited to any particular type of operations, functions, applications or services.

In some instances, operations performed by the electronic device 100 may sometimes require generation of signals with particular characteristics, such as frequencies. For example, the electronic device 100 may be utilized in communication of data, such as using available wireless or wired connections. In this regard, data may be communicated using radio frequency (RF) signals, which may be communicated to and/or from the electronic device 100 over supported wired or wireless interfaces. Processing signals in the electronic device 100 may be performed using suitable components or circuits (e.g., in the communication subsystem 130), in which signals may be generated for use as baseband signals or carrier signals for example. The electronic device 100 may also be utilized in generating audio signals (e.g., for output via speakers), such as based on digital audio content obtained from local sources (storage media), remote sources (e.g., broadcast nodes), or user input (e.g., clicks corresponding to interactions with touchscreen). Various methods may be used in generating signals required by the electronic device 100. For example, one of the more common methods for generating signals (e.g., for use in signal processing) may be using oscillator circuits. In this regard, oscillator circuits may be operable to produces repetitive, oscillating electronic signal (e.g., a sine wave) based on some form of input (e.g., voltage). Signal generation in the electronic device 100 may, in some instances, entail or comprise frequency synthesis. In this regard, frequency synthesis may comprise generating various ranges of frequencies from a single fixed source (e.g., oscillator). Frequency synthesis may be used in such systems or applications as, for example, communications (e.g., radio receivers, mobile telephones, radiotelephones, walkie-talkies, satellite receivers, navigational systems, etc.), audio processing or the like. Frequency synthesis may comprise such operations as frequency multiplication, frequency division, and frequency mixing (the frequency mixing process generates sum and difference frequencies) operations to produce the desired output signal.

In example implementation, the electronic device 100 may incorporate a plurality of phase-locked loop (PLL) circuits, for use in signal generation related operations. In this regard, a PLL may be operable to generate output signal(s) whose phase may be related to the phase of an input (reference) signal. PLL circuits may typically comprise some sort of variable frequency oscillator (e.g., voltage controlled oscillator or VCO) and a phase detector, with the phase detector being utilized to compare the phase of the reference signal with the phase of the signal derived from the output of the oscillator (e.g., to enable determining necessary adjustments to the frequency of its oscillator to keep the phases matched). The signal from the phase detector may then be used to control the oscillator in a feedback loop manner. Because frequency relate to phase (e.g., frequency is the time derivative of phase), keeping the input and output phase locked may allow keeping the input and output frequencies in lock as well. Consequently, PLLs may be utilized to track input frequencies, and/or to generate output frequencies related thereto (a frequency that is a multiple of an input frequency). Such frequency control may be utilized in various processing operations, such as demodulation, frequency synthesis, and the like. PLLs are widely employed in radio, communications, computers and other electronic applications. In this regard, PLLs may be utilized to enable recovering signals from a noisy communication channel, generate stable frequencies at a multiple of an input frequency (frequency synthesis), or distribute clock timing pulses various circuits or systems (e.g., microprocessors, such as the processors 110).

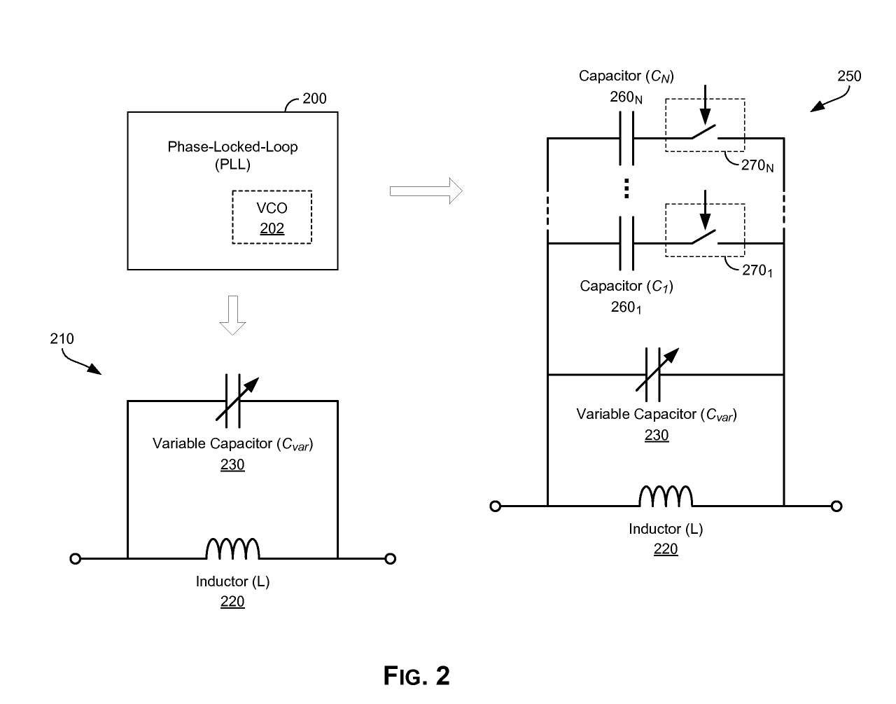

Signal generation (e.g., using PLL circuits) may be subject, in some instances, to disturbances, such as due to particular conditions that may be affect the signal generation. In this regard, condition that may affect signal generation may comprise environmental conditions (e.g., temperature), physical conditions (e.g., movement, rotation or shaking of system incorporating the signal generator), functional conditions—i.e., conditions relating directly to the signal generation (e.g., supply variations), and/or the like. The disclosure, however, is not limited to any particular type of conditions. Accordingly, in various implementations of the invention, an enhanced architecture may be utilized in implementing components (e.g., PLLs) used in generation of signals in electronic devices, such as the electronic device 100. In this regard, such enhanced architecture may enable expedited modification when changing output signals, and/or providing adaptive and dynamic tuning, to ensure that an output signal may be maintained when there may be change in conditions affecting signal generation (e.g., change in temperature, which may be detected using the sensory subsystem 150 for example, voltage/supply variations, etc.). An example of such enhanced architecture is described in more detail in connection with FIG. 2.

FIG. 2 illustrates an example variable capacitor based component of a voltage-controlled-oscillator (VCO), in accordance with an implementation of the invention. Referring to FIG. 2 there is shown a Phase-Locked-Loop (PLL) 200.

The PLL 200 may comprise suitable logic, circuitry, interfaces, and/or code that may be operable to generate local oscillator (LO) signals, in a system comprising the PLL 200 (e.g., the electronic device 100 of FIG. 1). In this regard, the LO signals (or derivatives thereof) may be used during and/or in support of various processing operations, such as in clocking (or driving clocking signals) of various circuits and components (e.g., clocking radio frequency (RF) transceivers, during various signal processing operations) and/or frequency synthesis. The PLL 200 may comprise, for example, a voltage controlled oscillator (VCO) 202, for use in generating LO signals. In this regard, the VCO 202 may comprise suitable logic, circuitry, interfaces, and/or code that may be operable to generate signals with particular frequencies. For example, the VCO 202 may be configured to generate signal(s) which may vary in frequency according to an input control voltage.

In operation, the PLL 200 may be utilized to generate signals that may have particular frequencies suited for particular purposes (e.g., clocking signals that are used in a RF down-convertor that may be used in down-converting incoming signals, through a mixer for example). In this regard, clock signals may typically be generated using oscillators based on input voltages (e.g., using the VCO 202 of the PLL 200).

The VCO 202 may be configured to generate signals having particular frequency, based on input voltage for example). The VCO 202 may be implemented using induction-capacitance based architecture, which may utilize a combination of induction and capacitance to control the output of the VCO (thus, frequency of the output signals). For example, in an example implementation, the VCO 202 may incorporate an inductor/capacitor (LC) tank 210, which may comprise an inductor 220 (having particular induction ‘L’) and a capacitor 230 (having particular capacitance ‘C’). In a VCO having such architecture, the VCO frequency (F_{VCO}) may be determined by the resonant frequency of an LC tank 210, where:

F_{VCO}=½π√LC (1)

With F_{VCO} being the frequency of the VCO, and ‘L’ being the induction of the inductor 220, and ‘C’ being the capacitance of the capacitor 230.

Accordingly, in induction-capacitance (LC) based implementations, the frequency of the VCO (F_{VCO}) may be adjusted by modifying one or both of the induction ‘L’ or the capacitance ‘C’ is changed. For example, in an example implementation variable capacitors (varactors) may be utilized used in various implementations, to allow adjusting VCO frequency VCO (F_{VCO}). In this regard, the capacitor 230 may be implemented as variable capacitor (varactor), whereby its capacitance may be adjusted (e.g., in response to input control signal or command). Thus, changing the capacitance (Cᵥₐᵣ) of the varactor 230 may result in adjustment to the frequency of VCO (F_{VCO}) in accordance with equation (1).

In some instances, digital tuning may be utilized to further enhance performance of a VCO (e.g., the VCO 202), such as by increasing the tuning range of the VCO. In this regard, digital tuning may allow intruding quick adjustments (e.g., in response to environmental changes), to maintain desired output. In LC based implementations, this may be achieved by incorporating a plurality of static capacitors that would allow quick changes in efficient manner (e.g., performance and cost). For example, the VCO 202 may be configured to incorporate a inductor/capacitor (LC) tank 250 that may comprise, in addition to the inductor 220 and the varactor 230, a plurality of capacitors C₁ (260₁)-C_{N} (260_{N}), with a corresponding plurality of switching elements 270₁-270_{N} (N being a non-zero natural number). In this regard, the plurality of capacitors 260₁-260_{N} and the corresponding plurality of switching elements 270₁-270_{N} may be utilized to configure a plurality of parallel tuning branches (e.g., N branches, with N being a positive integer) with each branch comprising a capacitor Cᵢ (260ᵢ) and a corresponding switching element 270ᵢ. Accordingly, the frequency of the VCO may be adjusted by, in addition to adjusting the capacitance of the varactor 230, by adjusting the number of capacitors tuned on (or off) from the branches. Thus, the total capacitance applicable to equation (1) may be determined as a summation of capacitance of the varactor 230 and capacitance of all capacitors 260ᵢ that are switched on (by closing corresponding switching elements 270ᵢ). In this regard, when the frequency of oscillation needs to be higher, more capacitors are switched off; and when the frequency of oscillation needs to be lower, more capacitors are switched on. A major difference between using varactors and digital tuning is that the capacitance change due to varactors is continuous, while the capacitance change in digital tuning is more abrupt.

While the VCO 202 may be locked by the PLL 200 to a certain frequency, the VCO 202 may need to change the number of turning-on capacitors in the LC tank 250. For example, characteristics of the VCO 202 may change, such as due to environmental conditions, for example due to change in temperature or supply variations. Thus, in order to remain locked at certain frequency, capacitances may be changed to maintain the VCO frequency (F_{VCO}). The change may also be due to user input, which may be intended to change the VCO frequency (F_{VCO}) while the PLL 200 is under locking condition. Such user-trigger change may also utilize a change in capacitance in the LC tank 250.

In various implementations of the invention, disturbances that may typically be created by switching on and off the digital tuning capacitors can be minimized. For example, this may be achieved by configuring control signals used in controlling operation of the switching elements (e.g., 270₁-270_{N}) that switch digital tuning branches to provide slow ramping during switching on or off. In other words, rather than having particular digital tuning capacitor 260ₓ be abruptly turned on or off (by simply implementing the corresponding switching element 270ₓ as simply an on/off switch), the control signal for the switching element 270ₓ may be configured to provide that switching as a plurality of incremental ramp-ups (or ramp-downs) between full switch-on and full switch-off. This enables achieving that change (between full switch-on and full switch-off) in a slow, continuous manner rather than as an abrupt jump. This is shown in more detail in FIG. 2 and the corresponding text.

While the disclosure thus far suggests a PLL being utilized during down-converting operations, the invention need not be so limited, and similar architecture and/or methods as described herein may be applied in other processing blocks or components, such as wherever a VCO may be needed or used.

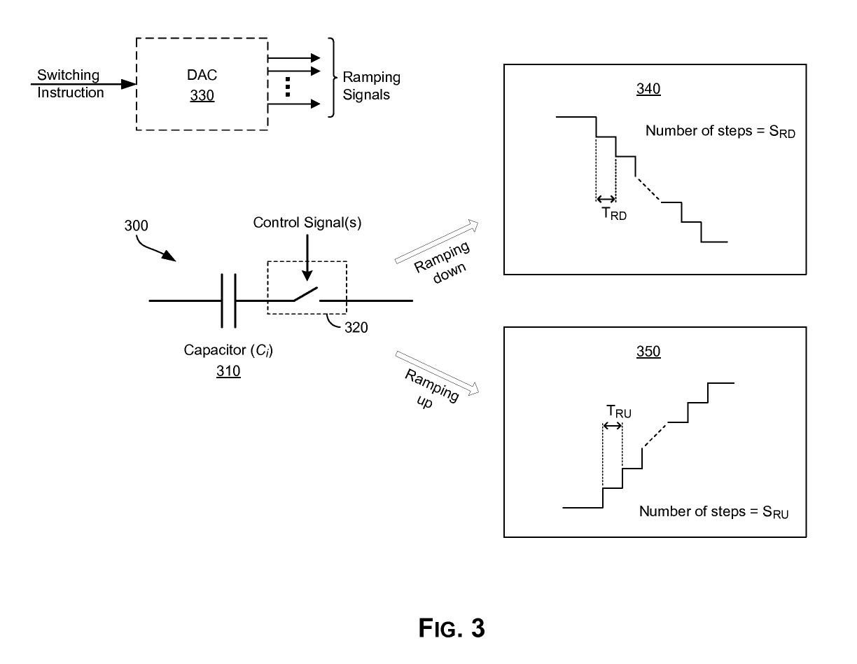

FIG. 3 illustrates an example use of ramping signals for controlling switching of capacitors in a voltage-controlled-oscillator (VCO), in accordance with an implementation of the invention. Referring to FIG. 3, there is shown a tuning branch 300, which may comprise a capacitor 310 and a corresponding switching element 320. In this regard, the capacitor 310 and the switching element 320 may correspond to any of the tuning branches of FIG. 2 (i.e., any capacitor 260ᵢ and switching element 270ᵢ combination of FIG. 2), for example.

In operations, the tuning branch 300 may be utilized in providing adaptive capacitance (or adjustment(s) thereto) in a system (e.g., in a VCO, such as the VCO 220). In this regard, the switching element 320 may be utilized to control switching of the capacitor 260ᵢ (i.e., connecting the capacitor 260ᵢ such as capacitance thereof may be applied). The switching element 320 may be controlled using a switching control signal, which may be used to control the switching operation (e.g., closing or opening) of the switching element 320.

In some instances, the switching control signal utilized in controlling operations of the switching element 320 may be configured to provide slow and/or incremental ramping during switching on or off of the digital tuning capacitor 310. In this regard, the switching provided by the switching element 320 may be performed in ramping scenario as a plurality of incremental ramp-ups (or ramp-downs), between full switch-on and full switch-off (rather than a single jump or transition between full switch-on and full switch-off). The ramping may be achieved by, for example, implementing the control signal for the switching element 320 as an analog (or analog-like) signal rather than a digital signal. In this regard, a digital-to-analog converter (DAC) 330 may be utilized, for example, to enable generating a plurality of ramping control signals (e.g., based on a single digital input, specifying a ‘switch off’ or a ‘switch on’ instruction) for controlling the switching element 320 to achieve the desired slow ramping. Thus, when increasing the capacitance is desired, ramping up signal(s) could be used; whereas when decreasing the capacitance is desired, ramping down signal(s) could be used. The speed of the ramping signal(s) may be adjusted depending on the requirement of the system. In some instances, output(s) of the DAC 330 may first be passed through filter(s), before being utilized as ramping control signals. In this regard, filtering the DAC outputs may enable reducing disturbances resulting from, for example, DAC switching. For example, in an implementation, for simplicity resistor-capacitor (RC) filters may be utilized. The disclosure is not limited, however, to any particular type of filters.

For example, a ramp-down profile 340 and a ramp-down profile 350 may be utilized in controlling the ramping of the switching elements 320, between full switch-on and full switch-off (as shown in FIG. 3). In this regard, each of the ramp-down profile 340 and the ramp-up profile 350 may have ramping characteristics associated therewith, determined based on preselected parameters corresponding to these characteristics, for example. The characteristics of the ramping profiles 340 and 350, between full switch-on and full switch-off, may comprise, for example, a number or ramping steps (e.g., defined by adjustment size parameters S_{RD} and S_{RU}, respectively) and/or duration of each step—i.e., time between each start of two consecutive steps (e.g., defined by duration parameters T_{RD} and T_{RU}, respectively).

In some instances, the ramping (up and/or down) characteristics may be controlled and/or adjusted or modified. For example, the number of steps and/or duration of the incremental steps between full switch-on and full switch-off may be adjusted (e.g., by modifying the parameters S_{RD} and/or T_{RD} for ramp-down profile 340, and parameters S_{RU} and/or T_{RU} for ramp-up profile 350). This may be achieved by, for example, adjusting the clocking of the DAC 330 being used in generating the control signals applied to switching element 320.

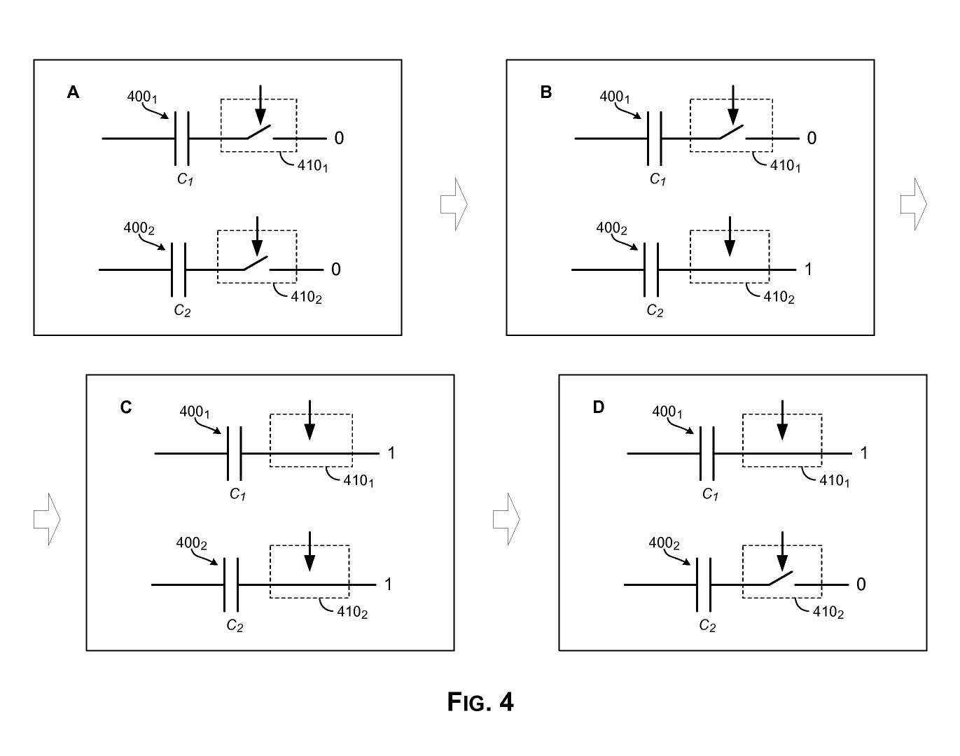

FIG. 4 illustrates an example ramping sequence in a voltage-controlled-oscillator (VCO), in accordance with an implementation of the invention. Referring to FIG. 4, there are shown two digital tuning capacitors (C₁) 400₁ and (C₂) 400₂, and two corresponding switching elements 410₁ and 410₂.

The two digital tuning capacitors 400₁ and 400₂ and the two corresponding switching elements 410₁ and 410₂ may correspond to two of the branches of FIG. 3, for example. Furthermore, each of the switching elements 410₁ and 410₂ may be controlled in a non-abrupt manner, such as by applying switching in a ramping manner, substantially as described with respect to switching element 320 of FIG. 3, for example.

In operation, switching of digital tuning capacitors may be staggered to further enhance performance (e.g., further minimizing abruptness and thus disturbance in the system). For example, in instances where both capacitors 400₁ and 400₂ are to be switched on, the switching on may be performed in a staggered manner—i.e., in sequence. Rather than initiating the switching (on) of capacitors 400₁ and 400₂ at the same time, one capacitor (e.g., capacitor 4000 may be switched on first, and only after that capacitor is fully switched on, a switching of the second capacitor (e.g., capacitor 400₂) may then be initiated. This is shown in FIG. 4 using the sequence A→B→C. Combining this staggered switching with the ramping control signals of the switching elements 410₁ and 410₂ (as shown in and described with respect to FIG. 3) may result in an almost continuous switching characteristic, thus reducing disturbance resulting from abrupt switching A similar approach may be applied in switching off scenarios. For example, in instances where both capacitors 400₁ and 400₂ are to be switched off, the switching off may be performed in a staggered manner—i.e., in sequence. Therefore, rather than initiating the switching (off) of capacitors 400₁ and 400₂ at the same time, one capacitor (e.g., capacitor 400₂) may be switched off first (as shown in reference D). Only after the first capacitor (capacitor 400₂) is fully switched off, a switching off of the second capacitor (e.g., capacitor 400₁) may then be initiated.

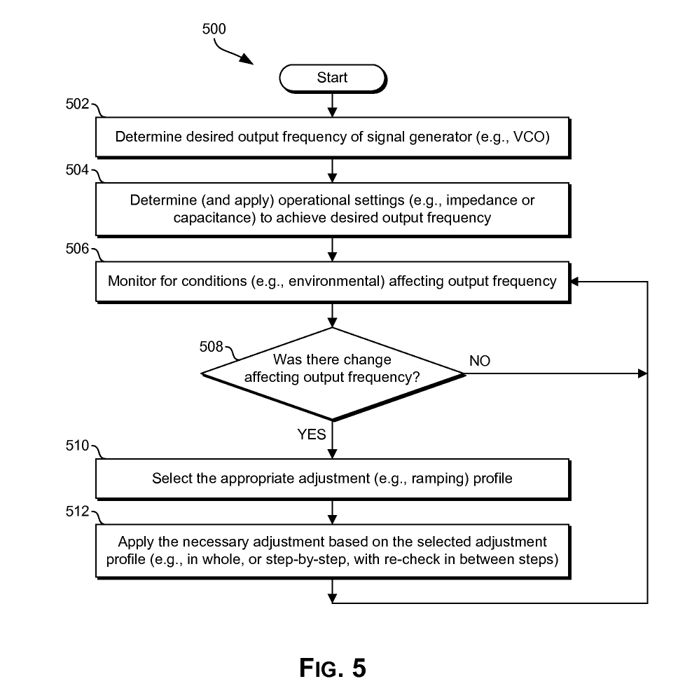

FIG. 5 is a flow chart that illustrates example process for controlling of capacitance ramping in a voltage-controlled-oscillator (VCO), in accordance with an implementation of the invention. Referring to FIG. 5, there is shown a flow chart 500 comprising a plurality of example steps.

In step 502, a desired output frequency for signal generator (e.g., a VCO, such as the VCO 202 of FIG. 2) may be determined. In this regard, determining the desired output frequency may be based on intended use(s) of generated/output signals (e.g., as clocking signals, for use in signal processing operation, frequency synthesis, etc.). In step 504, based on determining of the desired output frequency, operational settings for the signal generator—e.g., to achieve desired output frequency—may be determined. For example, in LC based implementations (e.g., such LC tank 250 of FIG. 2), pertinent operations settings may comprise impedance (‘L’) and capacitance (‘C’). In a variable capacitor based implementation, the impedance may remain largely unchanged, with adjustment in the output frequency being achieved by means of capacitance adjustment (e.g., variably and adaptively setting the variable capacitor, such as the varactor 230 of FIG. 2). In step 506, conditions (e.g., environmental) affecting output frequency may be monitored, to determine when/if there may be any condition (or change thereto) that may affect the output frequency. In step 508, a check may be done to determine whether there has been a condition (or change) that affects the output frequency of the signal generator. In instances where it may be determined that there would be no effect on the output frequency, the process may loop back to step 506, to continue monitoring.

Returning to step 508, in instances where it may be determined that a condition (or change) has (or may) affect the output frequency, the process may proceed to step 510. In step 510, an adjustment that may ensure maintaining the output frequency may be determined. In this regard, in some implementations, determining the necessary adjustment(s) may be done by selecting an appropriate adjustment profile. In this regard, in instances where the signal generator may incorporate a plurality of incremental adjustment elements (e.g., plurality of static capacitors, such as capacitors 260₁-260_{N}), the adjustment profile may comprise, for example, a ramping profile, that may allow for switching on/off each of the incremental adjustment elements one-by-one, such as until the output frequency is restored. In step 512, the necessary adjustment(s) to maintain/restore the desired output frequency may be applied—e.g., based on the selected adjustment profile, which may either be applied in whole, or incrementally (step-by-step, with re-check in between steps).

Other implementations may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the steps as described herein for voltage-controlled-oscillator (VCO) architecture for reducing disturbance.

Accordingly, the present method and/or system may be realized in hardware, software, or a combination of hardware and software. The present method and/or system may be realized in a centralized fashion in at least one computer system, or in a distributed fashion where different elements are spread across several interconnected computer systems. Any kind of computer system or other system adapted for carrying out the methods described herein is suited. A typical combination of hardware and software may be a general-purpose computer system with a computer program that, when being loaded and executed, controls the computer system such that it carries out the methods described herein.

The present method and/or system may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present method and/or apparatus has been described with reference to certain implementations, it will be understood by those skilled in the art that various changes may be made and equivalents may be substituted without departing from the scope of the present method and/or apparatus. In addition, many modifications may be made to adapt a particular situation or material to the teachings of the present disclosure without departing from its scope. Therefore, it is intended that the present method and/or apparatus not be limited to the particular implementations disclosed, but that the present method and/or apparatus will include all implementations falling within the scope of the appended claims.

What is claimed is:

1. A system, comprising:
one or more circuits for use in controlling a signal generator, wherein the signal generator is configurable to generate signals at one or more particular frequencies, the one or more one or more circuits being operable to:
set frequency of an output of the signal generator by setting one or both of impedance and capacitance associated with the signal generator; and
tune the signal generator by applying one or more adjustments to the impedance and the capacitance associated with the signal generator, to maintain the set frequency.

2. The system of claim 1, wherein the one or more circuits are operable to determine when the one or more adjustments are needed based on a plurality of conditions affecting output frequency of the signal generator.

3. The system of claim 2, wherein the one or more circuits are operable to monitor the plurality of conditions affecting output frequency of the signal generator.

4. The system of claim 1, wherein the signal generator comprises a phase-locked loop (PLL).

5. The system of claim 4, wherein the phase-locked loop (PLL) comprises a voltage controlled oscillator (VCO) for use in generating oscillating signals driving the generation of the output of the PLL.

6. The system of claim 1, wherein the one or more circuits are operable to tune the signal generator, to maintain the set frequency, by switching on or off one or more of a plurality of tuning branches.

7. The system of claim 6, wherein the one or more circuits are operable to switch the one or more of the plurality of tuning branches based on ramping control signals.

8. The system of claim 7, wherein the one or more circuits are operable to generate the ramping control signals.

9. A method, comprising:
controlling a signal generator that is configurable to generate signals at one or more particular frequencies, the controlling comprising:
setting frequency of an output of the signal generator by setting one or both of impedance and capacitance associated with the signal generator; and
tuning the signal generator by applying one or more adjustments to the impedance and the capacitance associated with the signal generator, to maintain the set frequency.

10. The method of claim 9, comprising determining when the one or more adjustments are needed based on a plurality of conditions affecting output frequency of the signal generator.

11. The method of claim 10, comprising monitoring the plurality of conditions affecting output frequency of the signal generator.

12. The method of claim 9, wherein the signal generator comprises a phase-locked loop (PLL).

13. The method of claim 12, wherein the phase-locked loop (PLL) comprises a voltage controlled oscillator (VCO) for use in generating oscillating signals driving the generation of the output of the PLL.

14. The method of claim 9, comprising tuning the signal generator, to maintain the set frequency, by switching on or off one or more of a plurality of tuning branches.

15. The method of claim 14, comprising switching the one or more of the plurality of tuning branches based on ramping control signals.

16. A system, comprising:
voltage controlled oscillator (VCO) for use in a Phase-Locked-Loop (PLL), wherein the VCO is configurable to generate signals at varying frequencies, the VCO comprising:
at least one impedance element;
at least one variable capacitance element; and
a plurality of tuning branches, wherein each tuning branch comprises at least a static capacitance element and a switching element.

17. The system of claim 16, wherein the at least one impedance element, the at least variable capacitance element, and the plurality of tuning branches are connected in parallel.

18. The system of claim 16, comprising determining frequency of output of the VCO based on combination of impedance of the at least one impedance element, capacitance of the at least variable capacitance element, and capacitance of each switched-on branch of the plurality of tuning branches.

19. The system of claim 18, comprising variably setting or adjusting the frequency of output of the VCO based on setting or modifying at least the capacitance of the at least variable capacitance element.

20. The system of claim 18, comprising tuning the frequency of the output of the VCO based on switching on or off one or more of the plurality of tuning branches.
